(19) United States
(12) Patent Application Publication
(10) Pub. No.: US 2013/0217220 A1
(43) Pub. Date: Aug. 22, 2013

(54) REPLACEMENT GATE ELECTRODE WITH A TANTALUM ALLOY METAL LAYER

(71) Applicants: Hemanth Jagannathan, Guilderland, NY (US); Vamsi K. Paruchuri, New York, NY (US)

(72) Inventors: Hemanth Jagannathan, Guilderland, NY (US); Vamsi K. Paruchuri, New York, NY (US)

(73) Assignee: International Business Machines Corporation, Armonk, NY (US)

(21) Appl. No.: 13/608,310

(22) Filed: Sep. 10, 2012

Related U.S. Application Data
(63) Continuation of application No. 13/398,314, filed on Feb. 16, 2012.

(51) Int. Cl. H01L 21/283

(52) U.S. Cl. 438/592; 257/E21.19

(57) ABSTRACT

A tantalum alloy layer is employed as a work function metal for field effect transistors. The tantalum alloy layer can be selected from TaC, TaAl, and TaAlC. When used in combination with a metallic nitride layer, the tantalum alloy layer and the metallic nitride layer provides two work function values that differ by 300 mV˜500 mV, thereby enabling multiple field effect transistors having different threshold voltages. The tantalum alloy layer can be in contact with a first gate dielectric in a first gate, and the metallic nitride layer can be in contact with a second gate dielectric having a same composition and thickness as the first gate dielectric and located in a second gate.

### CROSS REFERENCE TO RELATED APPLICATION

This application is a continuation of U.S. patent application Ser. No. 13/398,314, filed Feb. 16, 2012 the entire content and disclosure of which is incorporated herein by reference.

### BACKGROUND

The present disclosure generally relates to semiconductor devices, and particularly to semiconductor structures including a tantalum alloy layer and a metallic nitride layer, and methods of manufacturing the same.

Satisfactory operation of p-type field effect transistors (PFETs) and n-type field effect transistors (NFETs) in a CMOS circuit require gate electrodes having work functions that differ by at least 300 mV˜400 mV. In order to provide multiple work functions having different work functions, a variety of work function metals are used in replacement gate integration schemes. However, such work function metals tend not to provide sufficiently low resistivity, thereby requiring deposition of additional fill metals with low resistivity. Thus, typical replacement gate electrodes include a stack of about 4-5 layers of different metals. With the scaling of semiconductor devices to the 22 nm node and the 14 nm node, filling narrow gate cavities employing a stack of different conductive material layers becomes more challenging.

### SUMMARY

A tantalum alloy layer is employed as a work function metal for field effect transistors. The tantalum alloy layer can be selected from TaC, TaAl, and TaAlC. When used in combination with a metallic nitride layer, the tantalum alloy layer and the metallic nitride layer provide two work function values that differ by 300 mV˜500 mV, thereby enabling multiple field effect transistors having different threshold voltages. The tantalum alloy layer can be in contact with a first gate dielectric in a first gate, and the metallic nitride layer can be in contact with a second gate dielectric having a same composition and thickness as the first gate dielectric and located in a second gate.

According to an aspect of the present disclosure, a semiconductor structure including at least two field effect transistors is provided. The semiconductor structure includes: a first field effect transistor including a first gate dielectric and a first gate electrode, wherein the first gate electrode includes a conductive tantalum alloy layer in contact with the first gate dielectric; and a second field effect transistor including a second gate dielectric and a second gate electrode, wherein the second gate electrode includes a metallic nitride layer in contact with the second gate dielectric.

According to another aspect of the present disclosure, a method of forming a semiconductor structure is provided. The method includes: forming a first gate cavity and a second gate cavity above a semiconductor portion, wherein each of the first gate cavity and the second gate cavity is laterally surrounded by a planarization dielectric layer, wherein a top surface of the semiconductor portion is exposed at a bottom of each of the first and second gate cavities; forming a gate dielectric layer within the first and second gate cavities; forming a first work function material layer directly on a first portion of the gate dielectric layer in the first gate cavity and a second work function material layer directly on a second portion of the gate dielectric layer in the second gate cavity, wherein one of the first and second work function material layers is a conductive tantalum alloy layer and another of the first and second work function material layers is a metallic nitride layer; and filling the first gate cavity and the second gate cavity with a conductive material, wherein a first conductive material portion is formed within the first gate cavity and a second conductive material portion is formed within the second gate cavity.

### BRIEF DESCRIPTION OF THE SEVERAL VIEWS OF THE DRAWINGS

FIG. 1 is vertical cross-sectional view of a first exemplary semiconductor structure after formation of disposable gate level layers according to a first embodiment of the present disclosure.

FIG. 2 is a vertical cross-sectional view of the first exemplary semiconductor structure after patterning of disposable gate structures and formation of source/drain extension regions according to the first embodiment of the present disclosure.

FIG. 3 is a vertical cross-sectional view of the first exemplary semiconductor structure after formation of spacers and source/drain regions according to the first embodiment of the present disclosure.

FIG. 4 is a vertical cross-sectional view of the first exemplary semiconductor structure after deposition and planarization of a planarization dielectric layer according to the first embodiment of the present disclosure.

FIG. 5 is a vertical cross-sectional view of the first exemplary semiconductor structure after removal of the disposable gate structures according to the first embodiment of the present disclosure.

FIG. 6 is a vertical cross-sectional view of the first exemplary semiconductor structure after formation of a gate dielectric layer and a first work function material layer according to the first embodiment of the present disclosure.

FIG. 7 is a vertical cross-sectional view of the first exemplary semiconductor structure after removal of exposed portions of the first work function material layer from a second field effect transistor region according to the first embodiment of the present disclosure.

FIG. 8 is a vertical cross-sectional view of the first exemplary semiconductor structure after formation of a second work function material layer according to the first embodiment of the present disclosure.

FIG. 9 is a vertical cross-sectional view of the first exemplary semiconductor structure after deposition of a conductive material layer according to the first embodiment of the present disclosure.

FIG. 10 is a vertical cross-sectional view of the first exemplary semiconductor structure after planarization according to the first embodiment of the present disclosure.

FIG. 11 is a vertical cross-sectional view of the first exemplary semiconductor structure after formation of a contact level dielectric layer and contact via structures according to the first embodiment of the present disclosure.

FIG. 12 is a vertical cross-sectional view of a second exemplary semiconductor structure after formation of semiconductor fins, disposable gate structures, source/drain extension regions, source/drain regions, and source/drain metal semiconductor alloy portions according to a second embodiment of the present disclosure.

FIG. 13 is a vertical cross-sectional view of the second exemplary semiconductor structure after deposition and planarization of a planarization dielectric layer according to the second embodiment of the present disclosure.

FIG. 14 is a vertical cross-sectional view of the second exemplary semiconductor structure after formation of a contact level dielectric layer and contact via structures according to the second embodiment of the present disclosure.

FIG. 15 is a vertical cross-sectional view of the second exemplary semiconductor structure of FIG. 14 along the vertical plane X-X′ in FIG. 13.

FIG. 16 is a vertical cross-sectional view of a third exemplary semiconductor structure after patterning of the second work function material layer according to a third embodiment of the present disclosure.

FIG. 17 is a vertical cross-sectional view of the third exemplary semiconductor structure after deposition of a conductive material layer according to the third embodiment of the present disclosure.

FIG. 18 is a vertical cross-sectional view of the third exemplary semiconductor structure after planarization according to the third embodiment of the present disclosure.

FIG. 19 is a vertical cross-sectional view of the third exemplary semiconductor structure after formation of a contact level dielectric layer and contact via structures according to the third embodiment of the present disclosure.

FIG. 20 is a vertical cross-sectional view of a fourth exemplary semiconductor structure according to a fourth embodiment of the present disclosure.

### DETAILED DESCRIPTION

As stated above, the present disclosure relates to semiconductor devices, and particularly to semiconductor structures including a tantalum alloy layer and a metallic nitride layer, and methods of manufacturing the same, which are now described in detail with accompanying figures. Like and corresponding elements mentioned herein and illustrated in the drawings are referred to by like reference numerals. The drawings are not necessarily drawn to scale.

As used herein, “a,” “one,” “another,” “even another,” “yet another,” “still another,” or other grammatical determiners are employed to distinguish one element from another element. As such, an element identified by a particular grammatical determiner in claims may, or may not, correspond to an element in the specification that employs the same grammatical determiner.

As used herein, “first,” “second,” “third,” and other ordinals are employed to distinguish one element from another element. As such, an element identified by a particular ordinal in claims may, or may not, correspond to an element in the specification that employs the same ordinal.

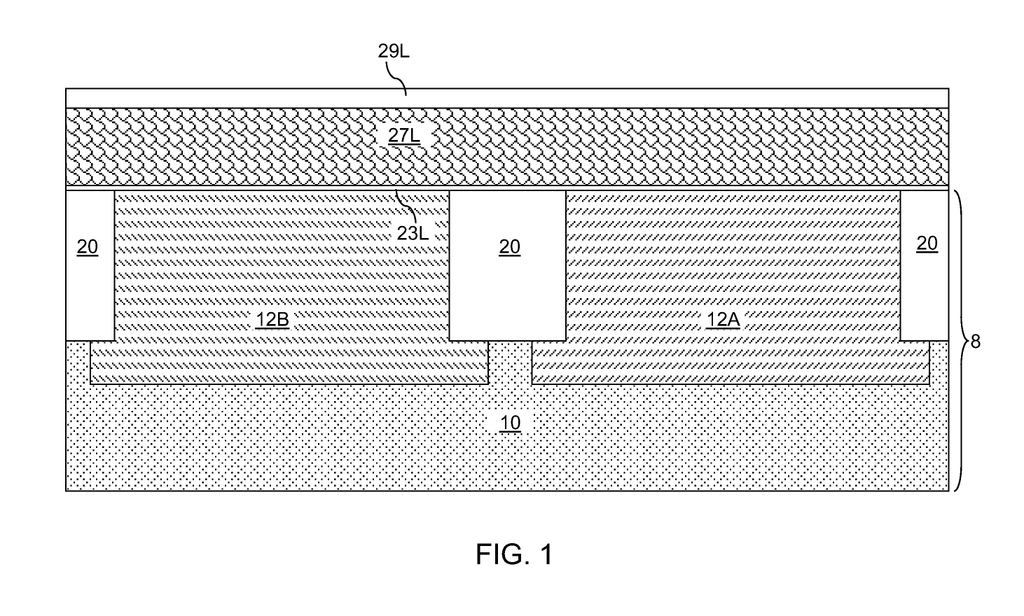

Referring to FIG. 1, a first exemplary semiconductor structure according to an embodiment of the present disclosure includes a semiconductor substrate 8, on which various components of field effect transistors are subsequently formed. The semiconductor substrate 8 can be a bulk substrate including a bulk semiconductor material throughout, or a semiconductor-on-insulator (SOI) substrate (not shown) containing a top semiconductor layer, a buried insulator layer located under the top semiconductor layer, and a bottom semiconductor layer located under the buried insulator layer.

Various portions of the semiconductor material in the semiconductor substrate 8 can be doped with electrical dopants of n-type or p-type at different dopant concentration levels. For example, the semiconductor substrate 8 may include an underlying semiconductor layer 10, a first doped well 12A formed in a first device region (the region on the left side in FIG. 1), and a second doped well 12B formed in a second device region (the region on the right side in FIG. 1). In one embodiment, the second doped well 12B can be doped with dopants of a first conductivity type, which can be n-type or p-type, and the first doped well 12A can be doped with dopants of a second conductivity type, which is the opposite of the first conductivity type. If the first conductivity type is p-type, the second conductivity type is n-type, and vice versa.

Shallow trench isolation structures 20 are formed to laterally separate each of the second doped well 12B and the first doped well 12A. Typically, each of the second doped well 12B and the first doped well 12A is laterally surrounded by a contiguous portion of the shallow trench isolation structures 20. If the semiconductor substrate 8 is a semiconductor-on-insulator substrate, bottom surfaces of the second doped well 12B and the first doped well 12A may contact a buried insulator layer (not shown), which electrically isolates each of the second doped well 12B and the first doped well 12A from other semiconductor portions of the semiconductor substrate 8 in conjunction with the shallow trench isolation structures 20. In one embodiment, topmost surfaces of the shallow trench isolation structures 20 can be substantially coplanar with topmost surfaces of the second doped well 12B and the first doped well 12A.

Disposable gate level layers are deposited on the semiconductor substrate 8 as blanket layers, i.e., as unpatterned contiguous layers. The disposable gate level layers can include, for example, a vertical stack of a disposable gate dielectric layer 23L, a disposable gate material layer 27L, and a disposable gate cap dielectric layer 29L. The disposable gate dielectric layer 23L can be, for example, a layer of silicon oxide, silicon nitride, or silicon oxynitride. The thickness of the disposable gate dielectric layer 23L can be from 1 nm to 10 nm, although lesser and greater thicknesses can also be employed. The disposable gate material layer 27L includes a material that can be subsequently removed selective to the dielectric material of a planarization dielectric layer to be subsequently formed. For example, the disposable gate material layer 27L can include a semiconductor material such as a polycrystalline semiconductor material or an amorphous semiconductor material. The thickness of the disposable gate material layer 27L can be from 30 nm to 300 nm, although lesser and greater thicknesses can also be employed. The disposable gate cap dielectric layer 29L can include a dielectric material such as silicon oxide, silicon nitride, or silicon oxynitride. The thickness of the disposable gate cap dielectric layer 29L can be from 3 nm to 30 nm, although lesser and greater thicknesses can also be employed. While the present disclosure is illustrated with disposable gate level layers including a vertical stack a disposable gate dielectric layer 23L, a disposable gate material layer 27L, and a disposable gate cap dielectric layer 29L, any other disposable gate level layers can also be employed provided that the material(s) in the disposable gate level layers can be removed selective to a planarization dielectric layer to be subsequently formed.

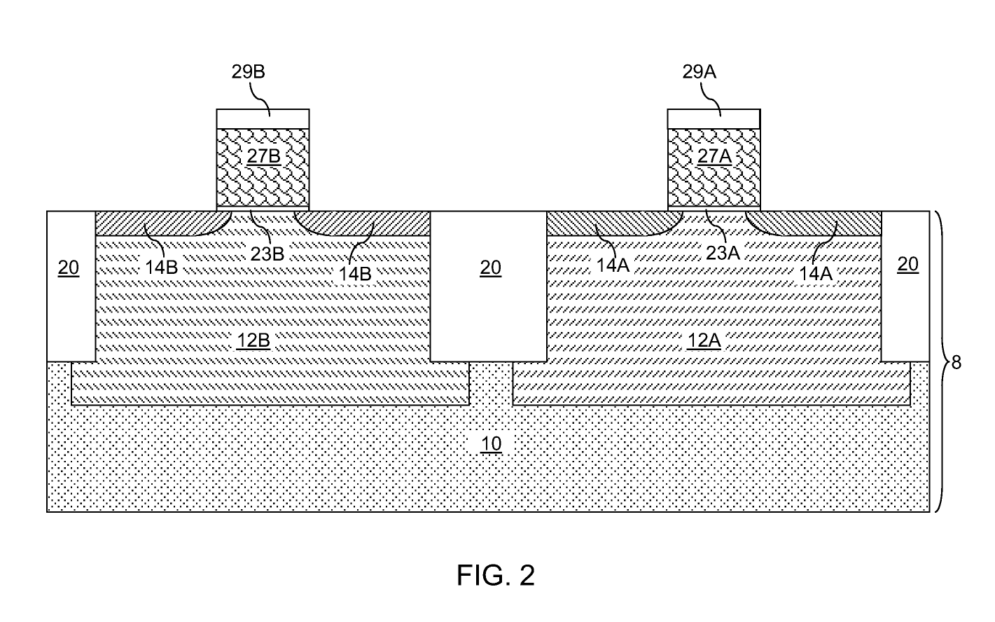

Referring to FIG. 2, the disposable gate level layers (29L, 27L, 23L) are lithographically patterned to form disposable gate structures. Specifically, a photoresist (not shown) is applied over the topmost surface of the disposable gate level layers (29L, 27L, 23L) and is lithographically patterned by lithographic exposure and development. The pattern in the photoresist is transferred into the disposable gate level layers (29L, 27L, 23L) by an etch, which can be an anisotropic etch such as a reactive ion etch. The remaining portions of the disposable gate level layers (29L, 27L, 23L) after the pattern transfer constitute disposable gate structures.

The disposable gate stacks may include, for example, a first disposable gate structure formed over the first doped well 12A in the first device region and a second disposable gate structure formed over the second doped well 12B in the second device region. The first disposable gate structure is a stack of a first disposable gate dielectric portion 23A, a first disposable gate material portion 27A, and a first disposable gate cap portion 29A, and the second disposable gate structure is a stack of a second disposable gate dielectric portion 23B, a second disposable gate material portion 27B, and a second disposable gate cap portion 29B. The first disposable gate cap portion 29A and the second disposable gate cap portion 29B are remaining portions of the disposable gate cap dielectric layer 29L. The first disposable gate material portion 27A and the second disposable gate material portion 27B are remaining portions of the disposable gate material layer 27L. The first disposable gate dielectric portion 23A and the second disposable gate dielectric portion 23B are remaining portions of the disposable gate dielectric layer 23L.

Masked ion implantations can be employed to form various source/drain extension regions. For example, dopants of the first conductivity type can be implanted into portions of the first doped well 12A that are not covered by the first disposable gate structure (23A, 27A, 29A) to form first source/drain extension regions 14A having a doping of the first conductivity type. The second doped well 12B can be masked by a patterned photoresist (not shown) during this implantation process to prevent implantation of additional dopants of the first conductivity type therein. As used herein, “source/drain extension regions” collectively refer to source extension regions and drain extension regions. Similarly, dopants of the second conductivity type can be implanted into portions of the second doped well 12B that are not covered by the second disposable gate structure (23B, 27B, 29B) to form second source/drain extension regions 14B. The first doped well 12A can be masked by another patterned photoresist (not shown) during this implantation process to prevent implantation of dopants of the second conductivity type therein.

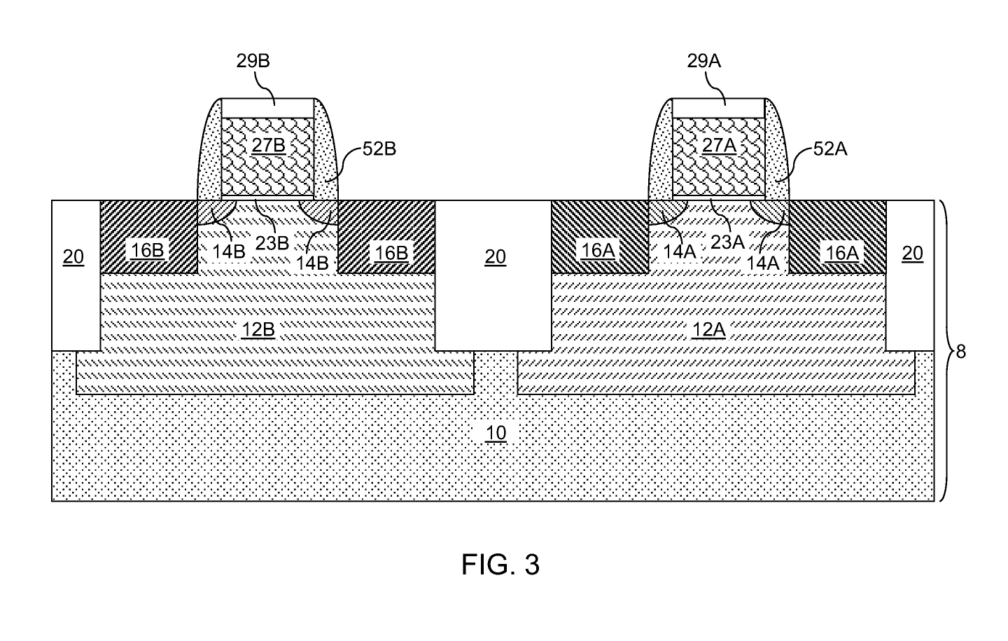

Referring to FIG. 3, gate spacers are formed on sidewalls of each of the disposable gate structures, for example, by deposition of a conformal dielectric material layer and an anisotropic etch. The gate spacers can include a first gate spacer 52A formed around the first disposable gate structure (23A, 27A, 29A) and a second gate spacer 52B formed around the second disposable gate structure (23B, 27B, 29B).

First source/drain regions 16A and second source/drain regions 16B are formed in the first doped well 12A and the second doped well 12B, respectively, by implanting electrical dopants, which can be p-type dopants or n-type dopants. Masked ion implantation can be employed to form the first source/drain regions 16A and the second source/drain regions 16B. Alternately, the first source/drain regions 16A and the second source/drain regions 16B can be formed as source/drain regions by substituting physically exposed portions of the first doped well 12A or the second doped well 12B with stress-generating semiconductor materials such as a silicon-germanium alloy or a silicon-carbon alloy. The embedded stress-generating semiconductor materials can be epitaxially aligned to the remaining portions of the first doped well 12A or the remaining portions of the second doped well 12B.

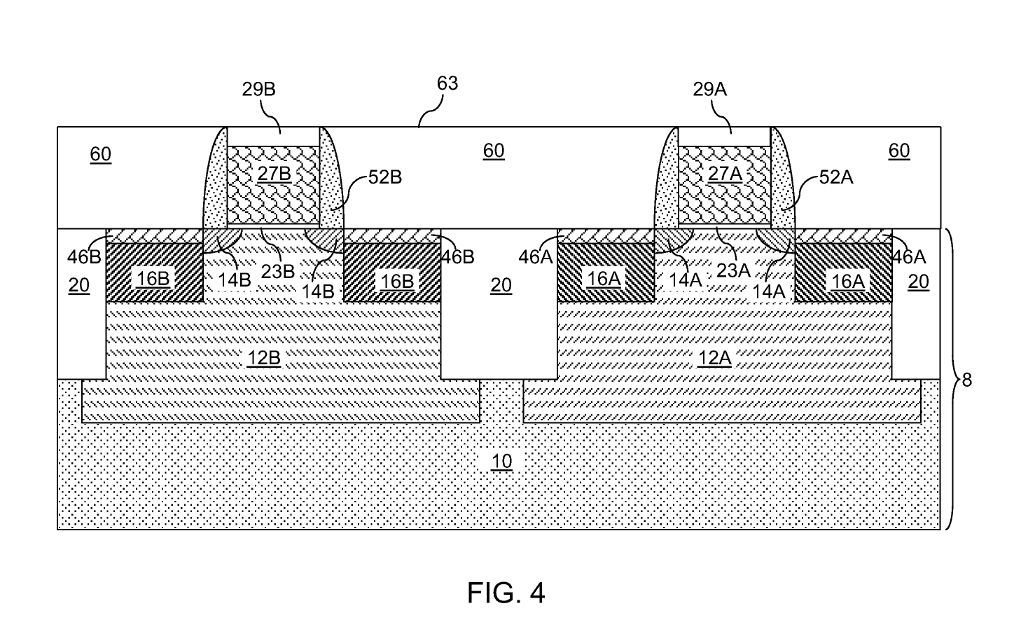

Referring to FIG. 4, first metal semiconductor alloy portions 46A and second metal semiconductor alloy portions 46B can be formed on exposed semiconductor material on the top surface of the semiconductor substrate 8, for example, by deposition of a metal layer (not shown) and an anneal. Unreacted portions of the metal layer are removed selective to reacted portions of the metal layer. The reacted portions of the metal layer constitute the metal semiconductor alloy portions (46A, 46B), which can include a metal silicide portions if the semiconductor material of the first and second source and drain regions (16A, 16B) include silicon.

The various metal semiconductor alloy portions (46A, 46B) include a first source-side metal semiconductor alloy portion (one of 46A′s) formed on the first source region (one of 16A′s), a first drain-side metal semiconductor alloy portion (the other of 16A′s) formed on the first drain region (the other of 16A′s), a second source-side metal semiconductor alloy portion (one of 46B′s) formed on the second source region (one of 16B′s), and a second drain-side metal semiconductor alloy portion (the other of 16B′s) formed on the second drain region (the other of 16B′s).

Optionally, a dielectric liner (not shown) may be deposited over the metal semiconductor alloy portions (46A, 46B), the first and second disposable gate structures (23A, 27A, 29A, 23B, 27B, 29B), and the first and second gate spacers (52A, 52B). Optionally, a first stress-generating liner (not shown) and a second stress-generating liner (not shown) can be formed over the first disposable gate structure (23A, 27A, 29A) and the second disposable gate structure (23B, 27B, 29B), respectively. The first stress-generating liner and the second stress-generating liner can include a dielectric material that generates a compressive stress or a tensile stress to underlying structures, and can be silicon nitride layers deposited by plasma enhanced chemical vapor deposition under various plasma conditions.

A planarization dielectric layer 60 can be deposited over the first stress-generating liner and/or the second stress-generating liner, if present, or over the metal semiconductor alloy portions (46A, 46B), the first and second disposable gate structures (23A, 27A, 29A, 23B, 27B, 29B), and the first and second gate spacers (52A, 52B) if (a) stress-generating liner(s) is/are not present. Preferably, the planarization dielectric layer 60 is a dielectric material that may be easily planarized. For example, the planarization dielectric layer 60 can be a doped silicate glass or an undoped silicate glass (silicon oxide).

The planarization dielectric layer 60 and any additional dielectric material layers (which include any of the first stress-generating liner, the second stress-generating liner, and the dielectric liner that are present, are planarized above the topmost surfaces of the first and second disposable gate structures (23A, 27A, 29A, 23B, 27B, 29B), i.e., above the topmost surfaces of the first and second disposable gate cap portions (29A, 29B). The planarization can be performed, for example, by chemical mechanical planarization (CMP). The planar topmost surface of the planarization dielectric layer 60 is herein referred to as a planar dielectric surface 63. The topmost surfaces of the disposable gate cap portions (29A, 29B) are coplanar with the planar dielectric surface 63 after the planarization.

The combination of the first source and drain extension regions 14A, the first source and drain regions 16A, and the first doped well 12A can be employed to subsequently form a first field effect transistor. The combination of the second source and drain extension regions 14B, the second source and drain regions 16B, and the second doped well 12B can be employed to subsequently form a second field effect transistor.

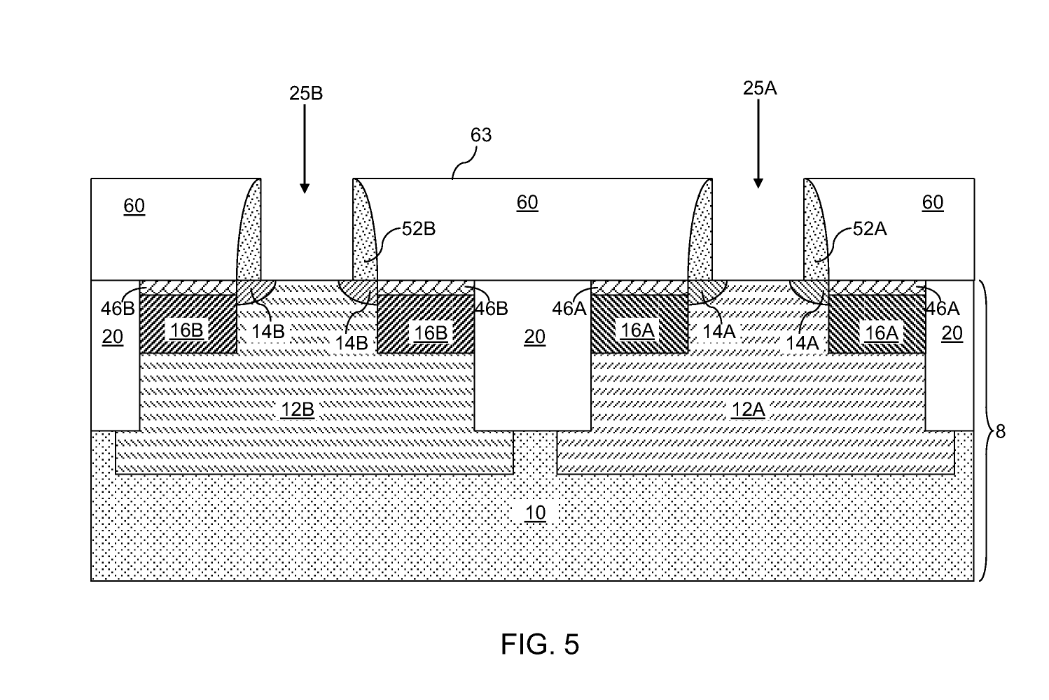

Referring to FIG. 5, the first disposable gate structure (23A, 27A, 29A) and the second disposable gate structure (23B, 27B, 29B) are removed by at least one etch. The first and second disposable gate structures (23A, 27A, 29A, 23B, 27B, 29B) can be removed, for example, by at least one etch, which can include an anisotropic etch, an isotropic etch, or a combination thereof. The at least one etch can include a dry etch and/or a wet etch. The at least one etch employed to remove the first and second disposable gate structures (23A, 27A, 29A, 23B, 27B, 29B) is preferably selective to the dielectric materials of the planarization dielectric layer 60 and any other dielectric material layer that is present above the semiconductor substrate 8.

A first gate cavity 25A is formed in the volume from which the first disposable gate structure (23A, 27A, 29A) is removed, and a second gate cavity 25B is formed in the volume from which the second disposable gate structure (23B, 27B, 29B) is removed. A semiconductor surface of the semiconductor substrate 8, i.e., the top surface of the first doped well 12A, is exposed at the bottom of the first gate cavity 25A. Another semiconductor surface of the semiconductor substrate 8, i.e., the top surface of the second doped well 12B, is exposed at the bottom of the second gate cavity 25B. Each of the first and second gate cavities (25A, 25B) is laterally surrounded by the planarization dielectric layer 60. The first gate spacer 52A laterally surrounds the first gate cavity 25A, and the second gate spacer 52B laterally surrounds the second gate cavity 25B. The inner sidewalls of the first gate spacer 52A can be substantially vertical, and extends from the top surface of the first doped well 12A to the planar dielectric surface 63, i.e., the topmost surface, of the planarization dielectric layer 60. Further, the inner sidewalls of the second gate spacer 52B can be substantially vertical, and extends from the top surface of the second doped well 12B to the planar dielectric surface 63 of the planarization dielectric layer 60.

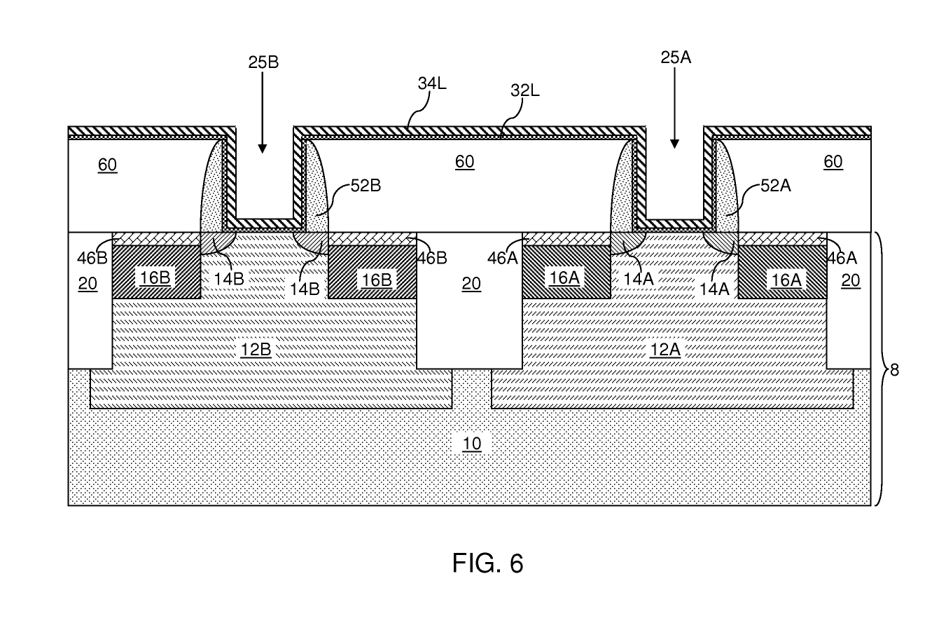

Referring to FIG. 6, a gate dielectric layer 32L is deposited on the bottom surfaces and sidewalls of the gate cavities (25A, 25B) and the topmost surface of the planarization dielectric layer 60. The gate dielectric layer 32L can be a high dielectric constant (high-k) material layer having a dielectric constant greater than 3.9. The gate dielectric layer 32L can include a dielectric metal oxide, which is a high-k material containing a metal and oxygen, and is known in the art as high-k gate dielectric materials. Dielectric metal oxides can be deposited by methods well known in the art including, for example, chemical vapor deposition (CVD), physical vapor deposition (PVD), molecular beam deposition (MBD), pulsed laser deposition (PLD), liquid source misted chemical deposition (LSMCD), atomic layer deposition (ALD), etc. Exemplary high-k dielectric material include HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, a silicate thereof, and an alloy thereof. Each value of x is independently from 0.5 to 3 and each value of y is independently from 0 to 2. The thickness of the gate dielectric layer 32L, as measured at horizontal portions, can be from 0.9 nm to 6 nm, and preferably from 1.0 nm to 3 nm. The gate dielectric layer 32L may have an effective oxide thickness on the order of or less than 2 nm. In one embodiment, the gate dielectric layer 32L is a hafnium oxide (HfO₂) layer.

A first work function material layer 34L including a first metallic material having a first work function is deposited. The first work function material layer 34L can be a p-type work function material layer or an n-type work function material layer. As used herein, a “p-type work function material” refers to a material having a work function that is between the valence band energy level of silicon and the mid band gap energy level of silicon, i.e., the energy level equally separated from the valence band energy level and the conduction band energy level of silicon. As used herein, an “n-type work function material” refers to a material having a work function that is between the conduction band energy level of silicon and the mid band gap energy level of silicon.

In one embodiment, the first work function material layer 34L is a conductive tantalum alloy layer. The conductive tantalum alloy layer can include a material selected from an alloy of tantalum and aluminum, an alloy of tantalum and carbon, and an alloy of tantalum, aluminum, and carbon. A first example of the conductive tantalum alloy layer is a tantalum-aluminum alloy layer, which includes an alloy of tantalum and aluminum. The atomic percentage of tantalum can be from 10% to 99%, and the atomic percentage of aluminum is from 1% to 90% in the alloy of tantalum and aluminum. The tantalum-aluminum alloy layer can consist essentially of tantalum and aluminium.

A second example of the conductive tantalum alloy layer is a tantalum carbide layer, which includes an alloy of tantalum and carbon. The atomic percentage of tantalum can be from 20% to 80%, and the atomic percentage of carbon can be from 20% to 80% in the alloy of tantalum and carbon. The tantalum carbide layer can consist essentially of tantalum and carbon.

A third example of the conductive tantalum alloy layer is a tantalum-aluminum carbide layer, which includes an alloy of tantalum, aluminum, and carbon. The atomic percentage of tantalum can be from 15% to 80%, the atomic percentage of aluminum can be from 1% to 60%, and the atomic percentage of carbon can be from 15% to 80% in the alloy of tantalum, aluminum, and carbon.

In another embodiment, the first work function material layer 34L is a conductive metallic nitride layer. For example, the first work function material layer 34L can be a titanium nitride layer consisting essentially of titanium nitride. The atomic percentage of titanium can be from 30% to 90%, and the atomic percentage of nitrogen can be from 10% to 70% in the titanium nitride layer.

The first work function material layer 34L can be deposited, for example, by atomic layer deposition (ALD), physical vapor deposition (PVD), or chemical vapor deposition (CVD). The first work function material layer 34L may, or may not, be conformal. In other words, the vertical portions of the first work function material layer 34L may, or may not, have the same thickness as the horizontal portions of the first work function material layer 34L. The thickness of the horizontal portions of the first work function material layer 34L at the bottom of the first and second gate cavities (25A, 25B) can be from 1.0 nm to 10 nm, although lesser and greater thicknesses can also be employed.

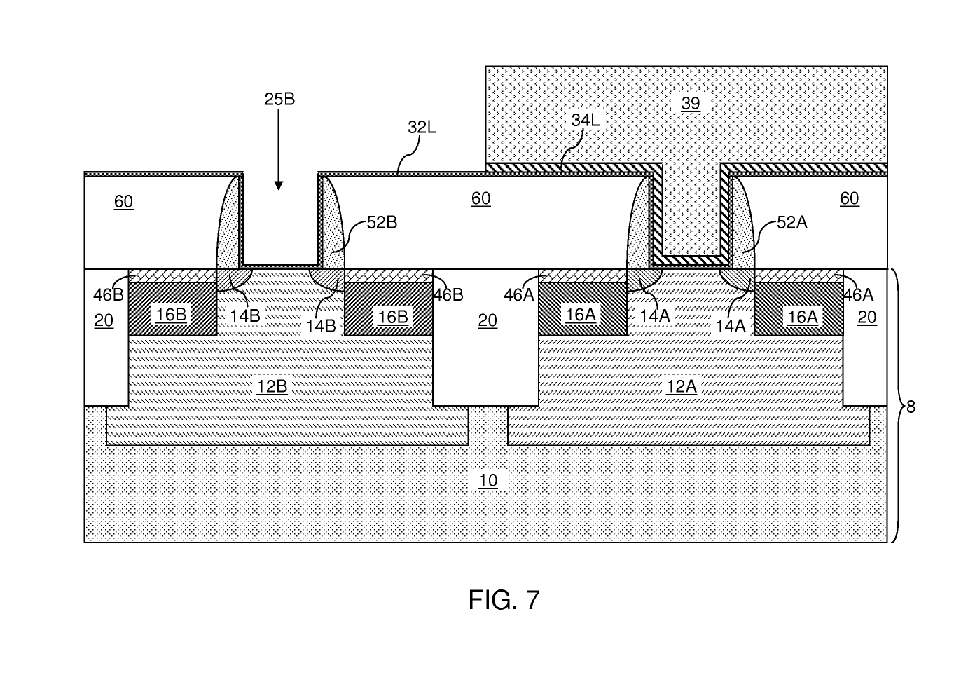

Referring to FIG. 7, a photoresist 39 is applied and lithographic patterned so that the photoresist 39 covers the area over the first doped well 12A, while the first work function material layer 34L is are exposed over the second doped well 12B. The exposed portion of the first work function material layer 34L is removed by an etch, which can be a wet etch or a dry etch, from within the second gate cavity 25B. A portion of the gate dielectric layer 32L is physically exposed at the bottom and sidewalls of the second gate cavity 25B. The photoresist 39 is removed, for example, by ashing or wet etching.

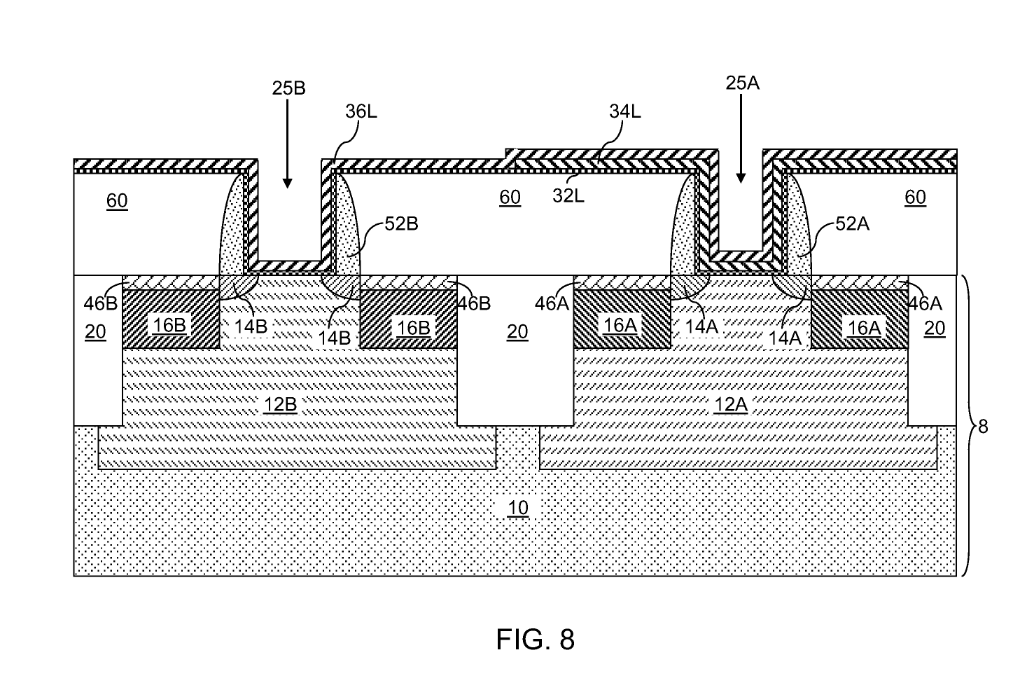

Referring to FIG. 8, a second work function material layer 36L including a second metallic material having a second work function is deposited.

In one embodiment, the first work function material layer 34L is a conductive tantalum alloy layer, the second work function material layer 36L is a conductive metallic nitride layer. For example, the second work function material layer 36L can be a titanium nitride layer consisting essentially of titanium nitride. The atomic percentage of titanium can be from 30% to 90%, and the atomic percentage of nitrogen can be from 10% to 70% in the titanium nitride layer. A portion of the metallic nitride layer is formed directly on the conductive tantalum alloy layer within the first gave cavity 25A.

In another embodiment, the first work function material layer 34L is a conductive metallic nitride layer, the second work function material layer 36L is a conductive tantalum alloy layer. The conductive tantalum alloy layer can include a material selected from an alloy of tantalum and aluminum, an alloy of tantalum and carbon, and an alloy of tantalum, aluminum, and carbon. The conductive tantalum alloy layer can be any of a tantalum-aluminum alloy layer, a tantalum carbide layer, and a tantalum-aluminum carbide layer, each of which can have the same composition as described above. A portion of the conductive tantalum alloy layer is formed directly on the metallic nitride layer within the first gate cavity 25A.

The second work function material layer 36L can be deposited, for example, by atomic layer deposition (ALD), physical vapor deposition (PVD), or chemical vapor deposition (CVD). The second work function material layer 36L may, or may not, be conformal. The thickness of the horizontal portions of the second work function material layer 36L at the bottom of the first and second gate cavities (25A, 25B) can be from 1.0 nm to 50 nm, although lesser and greater thicknesses can also be employed.

Thus, the first work function material layer 34L is formed directly on a first portion of the gate dielectric layer 32L in the first gate cavity 25A, and the second work function material layer 34L is formed directly on a second portion of the gate dielectric layer 32L in the second gate cavity 25B. One of the first and second work function material layers (34L, 36L) is a conductive tantalum alloy layer, and another of the first and second work function material layers (34L, 36L) is a metallic nitride layer.

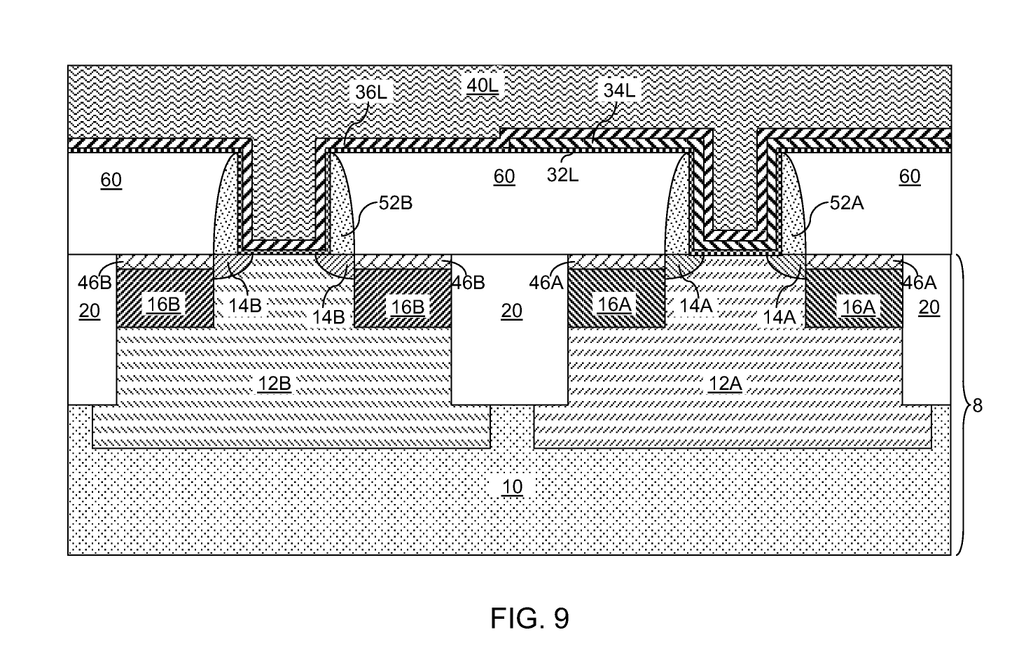

Referring to FIG. 9, the gate cavities (25A, 25B) are filled with a conductive material layer 40L. The conductive material layer 40L is deposited directly on the tungsten barrier layer 38L. The conductive material layer 40L includes a metal, which can be deposited by physical vapor deposition or chemical vapor deposition. For example, the conductive material layer 40L can be an aluminum or tungsten layer or an aluminum or tungsten alloy layer deposited by physical vapor deposition. The thickness of the conductive material layer 40L, as measured in a planar region of the conductive material layer 40L above the top surface of the planarization dielectric layer 60, can be from 100 nm to 500 nm, although lesser and greater thicknesses can also be employed. In one embodiment, the conductive material layer 40L can include at least one material selected from W and Al. Further, the conductive material layer 40L can consist essentially of a single elemental metal such as W or Al.

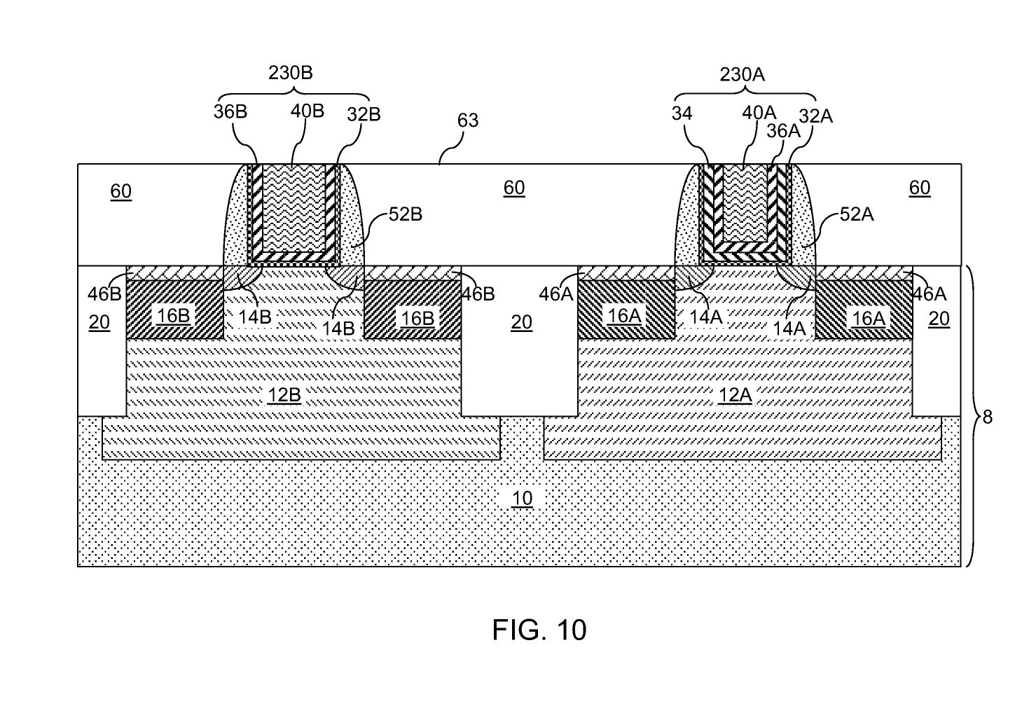

Referring to FIG. 10, the conductive material layer 40L, the second work function material layer 36L, the first work function material layer 34L, and the gate dielectric layer 32L are planarized, for example, by chemical mechanical planarization. Specifically, portions of the conductive material layer 40L, the second work function material layer 36L, the first work function material layer 34L, and the gate dielectric layer 32L are removed from above the planar dielectric surface 63 of the planarization dielectric layer 60 at the end of the planarization step. The remaining portion of the gate dielectric layer 32L in the first device region forms a first gate dielectric 32A, and the remaining portion of the gate dielectric layer 32L in the second device region forms a second gate dielectric 32B. The remaining portion of the first work function material layer 34L in the first device region forms a first work function material portion 34. The remaining portion of the second work function material layer 36L in the first device region forms a second work function material portion 36A. The remaining portion of the second work function material layer 36L in the second device region forms a work function material portion 36B. The remaining portion of the conductive material layer 40L in the first device region constitutes a first metal portion 40A, and the remaining portion of the conductive material layer in the second deice region constitutes a second metal portion 40B. The topmost surfaces of the first and second gate dielectrics (32A, 32B), the first and second work function material portions (34, 36A), the work function material portion 36B, and the first and second metal portions (40A, 40B) are coplanar with the topmost surface of the planarization dielectric layer 60.

Thus, replacement gate stacks are formed within the volume previously occupied by the first and second gate cavities (25A, 25B) at the step of FIG. 6. The replacement gate stacks include a first replacement gate stack 230A located in the first device region and a second replacement gate stack 230B located in the second device region. Each replacement gate stack (230A, 230B) overlies a channel region of a field effect transistor. The first replacement gate stack 230A and the second replacement gate stack 230B are formed concurrently.

A first field effect transistor is formed in the first device region. The first field effect transistor includes the first doped well 12A, the first source/drain extension regions 14A, the first source/drain regions 16A, the first metal semiconductor alloy portions 46A, the first replacement gate stack 230A, and the first gate spacer 52A. The first replacement gate stack 230A includes the first gate dielectric 32A, the first work function material portion 34, the second work function material portion 36A, and the first metal portion 40A.

A second field effect transistor is formed in the second device region. The second field effect transistor includes the second doped well 12B, the second source/drain extension regions 14B, the second source/drain regions 16B, second metal semiconductor alloy portions 46B, the second replacement gate stack 230B, and the second gate spacer 52B. The second replacement gate stack 230B includes the second gate dielectric 32B, the work function material portion 36B, and the second metal portion 40B. The second work function material portion 36A in the first replacement gate stack 230A and the work function material portion 36B in the second replacement gate stack 230B have the same material composition and the same thickness.

Each of the first and second field effect transistors is a planar field effect transistor having a channel located underneath a topmost surface of a semiconductor substrate. One of the first and second field effect transistors includes a gate electrode that includes a conductive tantalum alloy layer and is in contact with a gate dielectric. The other of the first and second field effect transistors includes another gate dielectric that includes a metallic nitride layer and is in contact with another gate dielectric.

In one embodiment, one of the first gate electrode and the second gate electrode can have a first work function that is closer to a conduction band of silicon than a mid-band gap level of silicon, and the other of the first gate electrode and the second gate electrode can have a second work function that is closer to a valence band of silicon than the mid-band gap level of silicon.

The first gate electrode 230A includes a first conductive material portion 40A in contact with the second work function material portion 36A, which is one of a metallic nitride layer and a conductive tantalum alloy layer. The second gate electrode 230B includes a second conductive material portion 40B in contact with another of the metallic nitride layer and the conductive tantalum alloy layer. The second conductive material portion 40B can have a same composition as the first conductive material portion 40A.

In one embodiment, the second gate electrode 230B includes a conductive tantalum alloy layer as the work function material portion 36B, and the first gate electrode 230A includes another conductive tantalum alloy layer as the second work function material portion 36A, which has a same composition and thickness as the conductive tantalum alloy layer. The conductive tantalum alloy layer in the first gate electrode 230A is in contact with the metallic nitride layer in the first gate electrode 230A, i.e., the first work function material portion 34, and is in contact with the first conductive material portion 40A. The conductive tantalum alloy layer is in contact with a second conductive material portion 40B having a same composition as the first conductive material portion 40A.

In another embodiment, the second gate electrode 230B includes a metallic nitride layer as the work function material portion 36B, and the first gate electrode 230A includes another metallic nitride layer as the second work function material portion 36A, which has a same composition and thickness as the metallic nitride layer. The metallic nitride layer in the first gate electrode 230A is in contact with the conductive tantalum alloy layer in the first gate electrode 230A, i.e., the first work function material portion 34, and is in contact with the first conductive material portion 40A. The conductive tantalum alloy layer is in contact with a second conductive material portion 40B having a same composition as the first conductive material portion 40A.

Each of the first and second gate dielectrics (32A, 32B) is a U-shaped gate dielectric, which includes a horizontal gate dielectric portion and a vertical gate dielectric portion extending upward from peripheral regions of the horizontal gate dielectric portion. In the first field effect transistor, the first work function material portion 34 contacts inner sidewalls of the vertical gate dielectric portion of the first gate dielectric 32A. In the second field effect transistor, the work function material portion 36B contacts inner sidewalls of the vertical gate dielectric portion of the second gate dielectric 32B. Each U-shaped gate dielectric is located on the semiconductor substrate 8 and is embedded in the planarization dielectric layer 60.

Each gate dielectric (32A, 32B), as a U-shaped gate dielectric, includes a horizontal gate dielectric portion and a vertical gate dielectric portion. The vertical gate dielectric portion contiguously extends from the horizontal gate dielectric portion to the topmost surface of the planarization dielectric layer 60.

If the second work function material portion 36A and the work function material portion 36B include a metallic nitride, each of the first and second conductive material portions (40A, 40B) contacts a portion of the metallic nitride layer upon formation. If the second work function material portion 36A and the work function material portion 36B include a conductive tantalum alloy, each of the first and second conductive material portions (40A, 40B) contacts a portion of the conductive tantalum alloy layer upon formation.

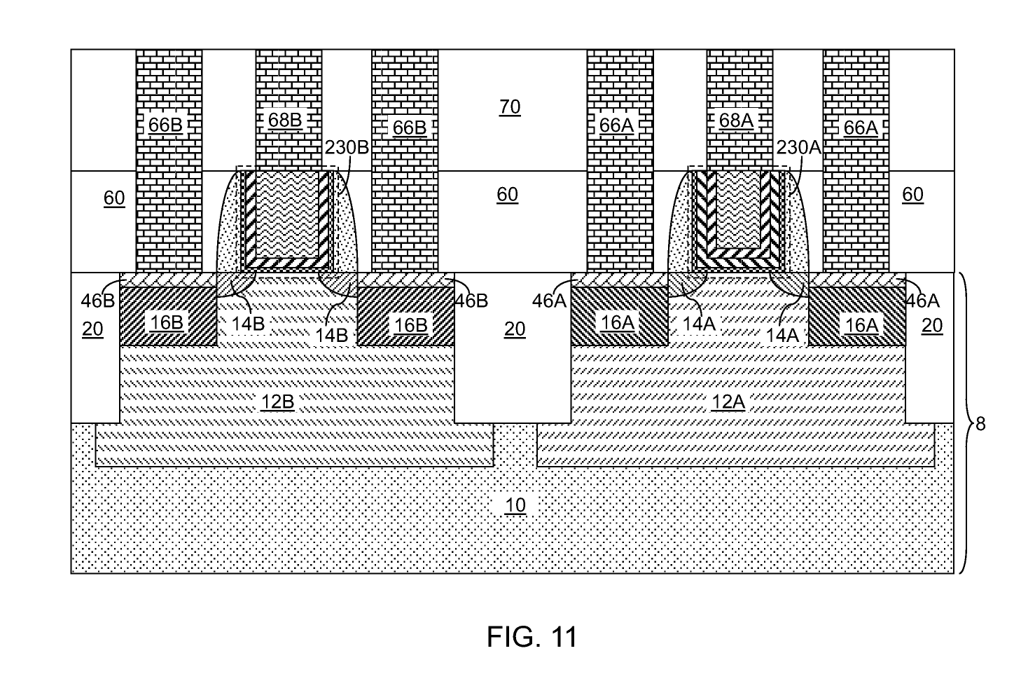

Referring to FIG. 11, a contact level dielectric layer 70 is deposited over the planarization dielectric layer 60. Various contact via structures can be formed, for example, by formation of contact via cavities by a combination of lithographic patterning and an anisotropic etch followed by deposition of a metal and planarization that removes an excess portion of the metal from above the contact level dielectric layer 70. The various contact via structures can include, for example, first source/drain contact via structures (i.e., at least one first source contact via structure and at least one first drain contact via structure) 66A, second source/drain contact via structures (i.e., at least one second source contact via structure and at least one second drain contact via structure) 66B, a first gate contact via structure 68A, and a second gate contact via structure 68B. Each source contact via structure (66A, 66B) and each drain contact via structure (66A, 66B) are embedded in the planarization dielectric layer 60 and the contact level dielectric material layer 70. Each source contact via structure (one of 66A and 66B) contacts a source-side metal semiconductor alloy portion (one of 46A and 46B), and each drain contact via structure (another of 66A and 66B) contacts a drain-side metal semiconductor alloy portion (another of 46A and 46B).

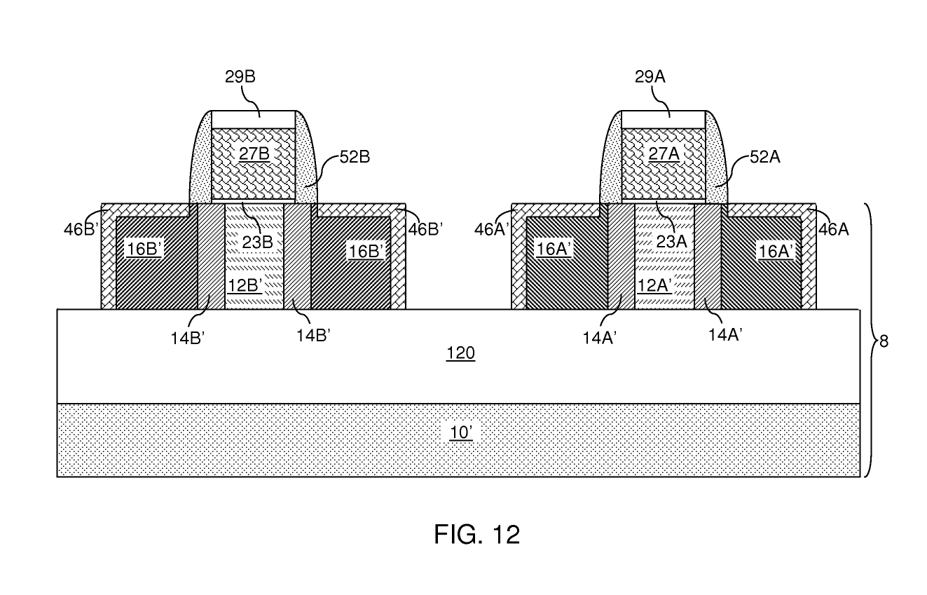

Referring to FIG. 12, a second exemplary semiconductor structure can be formed, for example, by patterning a semiconductor-on-insulator (SOI) substrate. Specifically, an SOI substrate including a top semiconductor layer, a buried insulator layer 120, and a handle substrate 10′ is provided. The top semiconductor layer is patterned to form a first semiconductor fin in a first device region and a second semiconductor fin in a second device region.

Disposable gate stacks are formed on the first and second semiconductor fins employing the same method as in the first embodiment. Further, first source/drain extension regions 14A′ are formed in the first semiconductor fin, and second source/drain extension regions 14B′ are formed in the second semiconductor fin. A first gate spacer 52A is formed around the first disposable gate structure (23A, 27A, 29A), and a second gate spacer 52B is formed around the second disposable gate structure (23B, 27B, 29B). First source and drain regions 16A′ are formed within the first semiconductor fin employing the first disposable gate structure (23A, 27A, 29A) and the first gate spacer 52A as a part of an implantation mask. Second source and drain regions 16A′ are formed within the second semiconductor fin employing the second disposable gate structure (23B, 27B, 29B) and the second gate spacer 52B as a part of an implantation mask. Unimplanted portions of the semiconductor material within each semiconductor fin constitute a first body portion 12A′ and a second body portion 12B′. Various metal semiconductor alloy portions (46A′, 46B′) can be formed on the first and second source and drain regions (16A′, 16B′) employing the same processing methods as in the first embodiment.

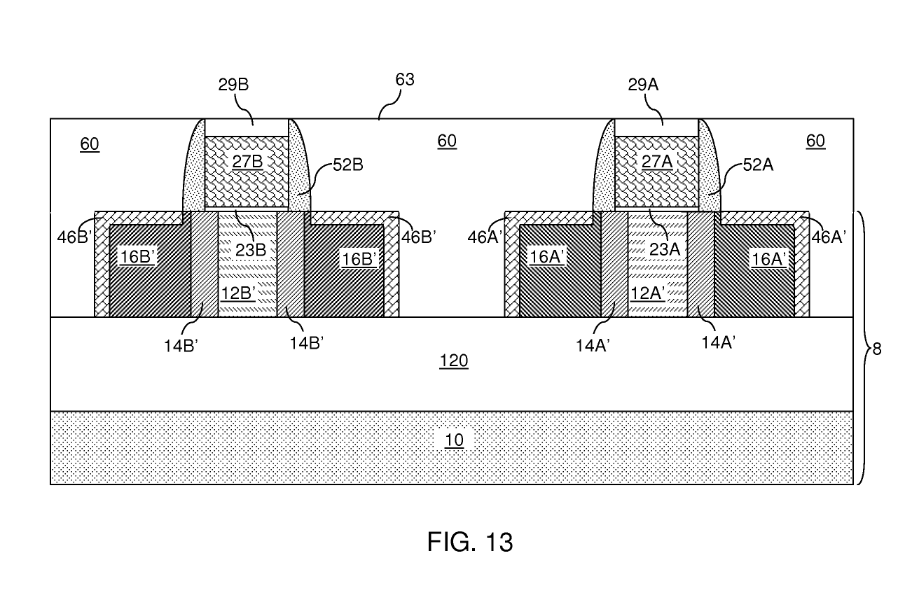

Referring to FIG. 13, a planarization dielectric layer 60 is deposited over the semiconductor fins, the disposable gate structures, and the buried insulator layer 120 and planarized employing the same processing steps as in the first embodiment, i.e., the processing steps of FIG. 4.

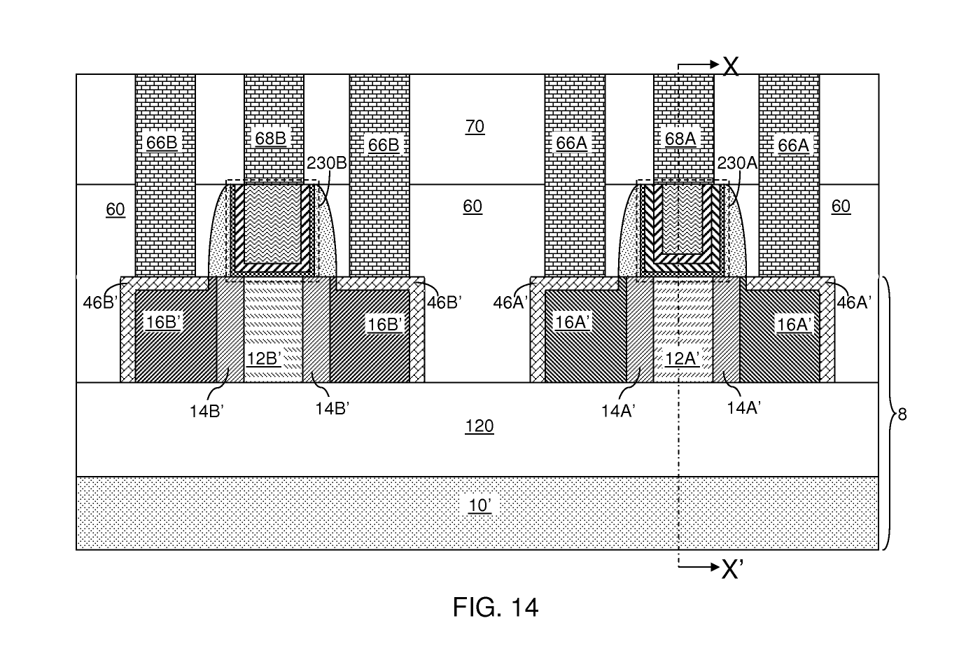

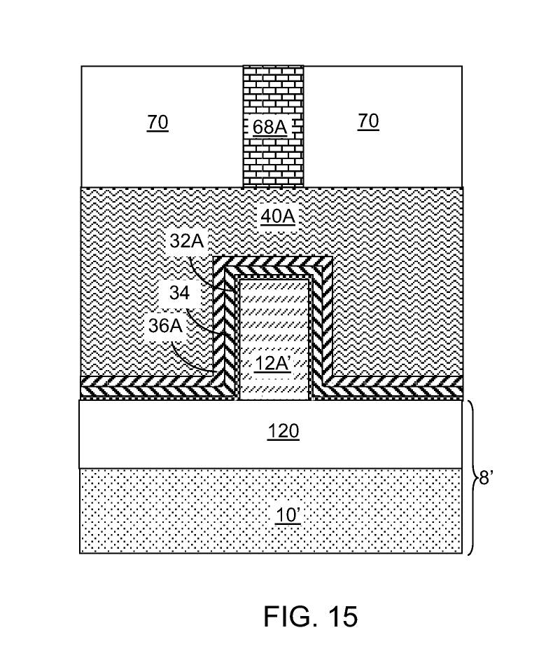

Referring to FIGS. 14 and 15, the same processing steps can be performed as in the first embodiment to form the second exemplary semiconductor structure illustrated in FIGS. 14 and 15. The second exemplary semiconductor structure includes the same features as the first exemplary semiconductor structure of FIG. 11 except that each of said first and second field effect transistors is a fin field effect transistor having a pair of channels located directly on sidewall portions of a semiconductor fin.

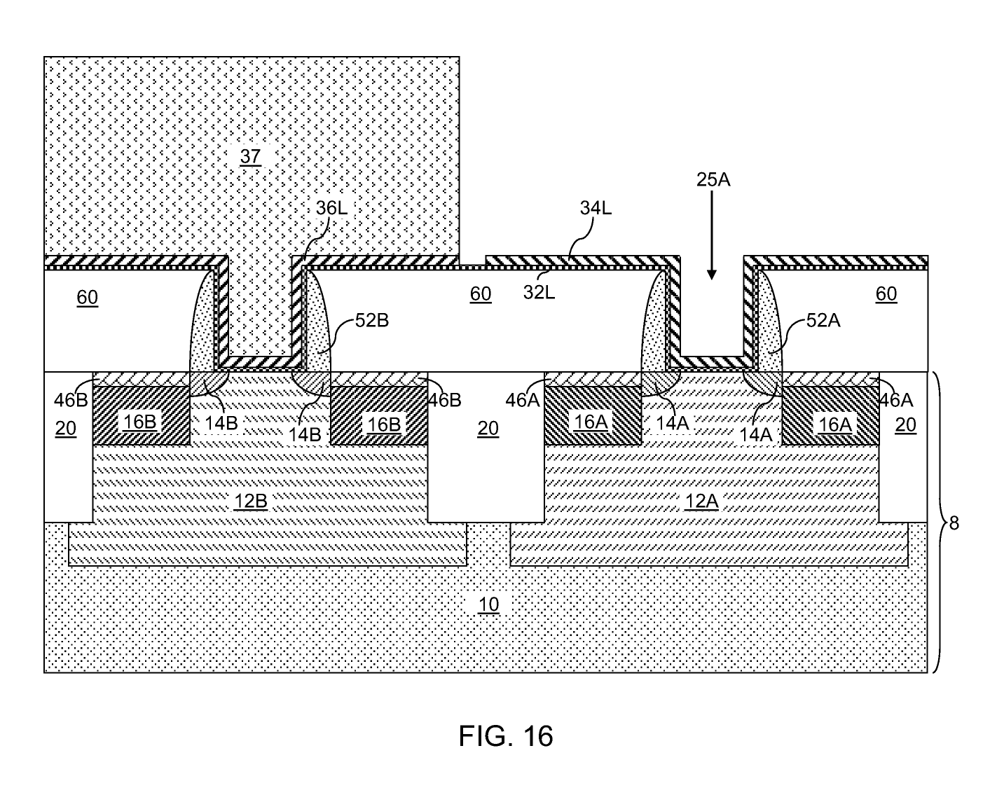

Referring to FIG. 16, a third exemplary semiconductor structure according to a third embodiment of the present disclosure is derived from the first exemplary semiconductor structure of FIG. 8 by applying a photoresist 37 over the first exemplary structure of FIG. 8, and subsequently patterning the photoresist 37 to cover the region of the second gate cavity 25B (See FIG. 8), while not coving the region of the first gate cavity 25A. The physically exposed portion of the second work function material layer 36L is removed by an etch, which can be a wet etch or a dry etch. The photoresist 37 is subsequently removed.

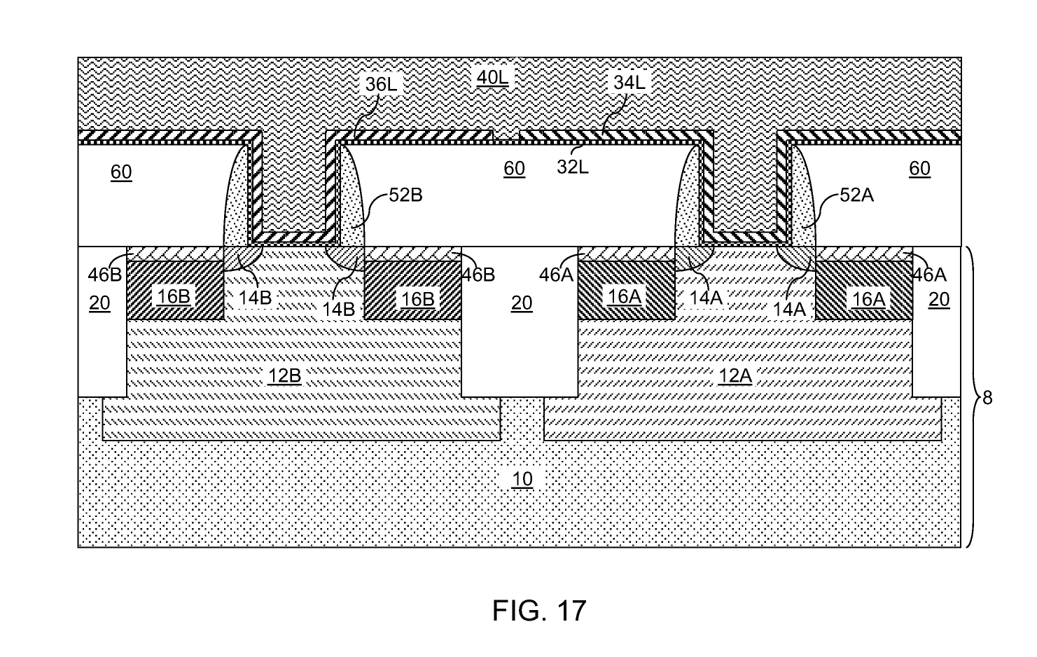

Referring to FIG. 17, a conductive material layer 40L is deposited in the first and second gate cavities (25A, 25B). The conductive material layer 40L can have the same composition and thickness as in the first embodiment, and can be deposited employing the same processing steps as in the first embodiment.

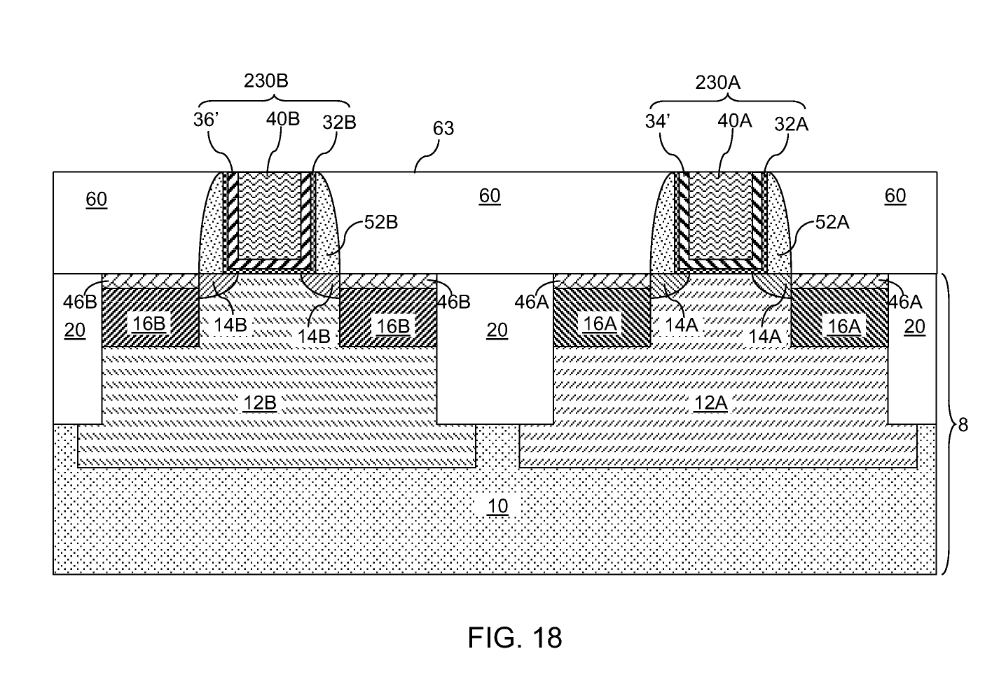

Referring to FIG. 18, the conductive material layer 40L, the second work function material layer 36L, the first work function material layer 34L, and the gate dielectric layer 32L are planarized, for example, by chemical mechanical planarization. The same processing step may be employed for planarization as in the first embodiment.

Specifically, portions of the conductive material layer 40L, the second work function material layer 36L, the first work function material layer 34L, and the gate dielectric layer 32L are removed from above the planar dielectric surface 63 of the planarization dielectric layer 60 at the end of the planarization step. The remaining portion of the gate dielectric layer 32L in the first device region forms a first gate dielectric 32A, and the remaining portion of the gate dielectric layer 32L in the second device region forms a second gate dielectric 32B. The remaining portion of the first work function material layer 34L in the first device region forms a first work function material portion 34′. The remaining portion of the second work function material layer 36L in the second device region forms a second work function material portion 36′. The remaining portion of the conductive material layer 40L in the first device region constitutes a first metal portion 40A, and the remaining portion of the conductive material layer in the second deice region constitutes a second metal portion 40B. The topmost surfaces of the first and second gate dielectrics (32A, 32B), the first and second work function material portions (34, 36A), the work function material portion 36B, and the first and second metal portions (40A, 40B) are coplanar with the topmost surface of the planarization dielectric layer 60.

A first work function material layer, i.e., the first work function material portion 34′, is in contact with a first portion of the gate dielectric layer 32L after formation of the first conductive material portion 40A. A second work function material layer, i.e., the second work function material portion 36′, is in contact with a second portion of the gate dielectric layer 32L after formation of the second conductive material portion 40B.

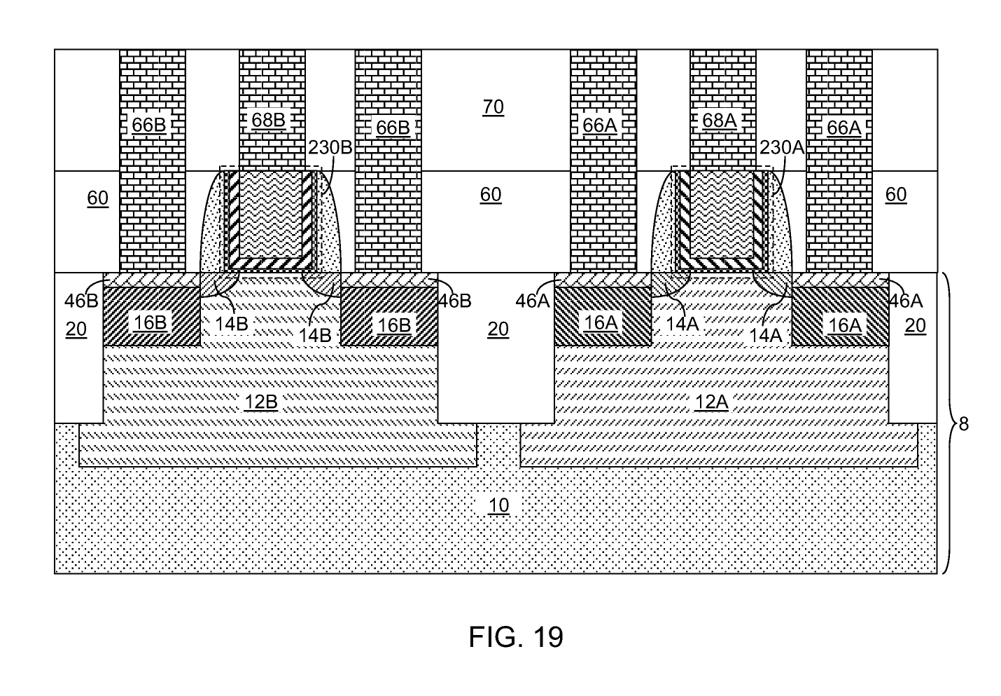

Referring to FIG. 19, a contact level dielectric layer 70 and various contact via structures (66A, 66B, 68A, 68B) can be formed, for example, by formation of contact via cavities by a combination of lithographic patterning and an anisotropic etch followed by deposition of a metal and planarization that removes an excess portion of the metal from above the contact level dielectric layer 70.

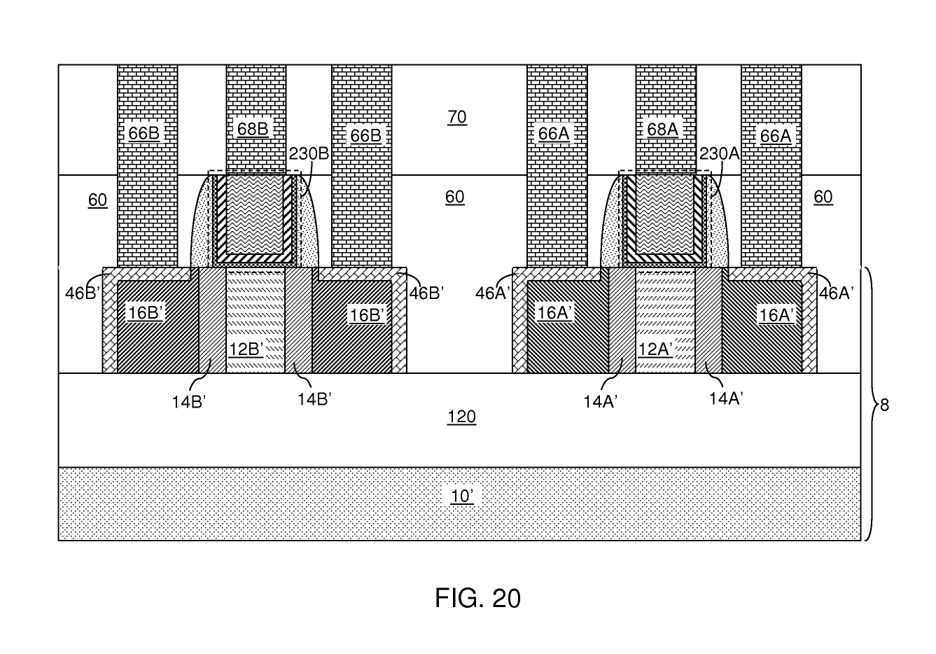

Referring to FIG. 20, a fourth exemplary semiconductor structure according to a fourth embodiment of the present disclosure can be derived from the second exemplary semiconductor structure of FIG. 13 by performing the processing steps of FIGS. 5-8 of the first embodiment and the processing steps of FIGS. 16-19 of the third embodiment. The fourth exemplary semiconductor structure includes the same features as the third exemplary semiconductor structure of FIG. 19 except that each of said first and second field effect transistors is a fin field effect transistor having a pair of channels located directly on sidewall portions of a semiconductor fin.

While the disclosure has been described in terms of specific embodiments, it is evident in view of the foregoing description that numerous alternatives, modifications and variations will be apparent to those skilled in the art. Each of the various embodiments of the present disclosure can be implemented alone, or in combination with any other embodiments of the present disclosure unless expressly disclosed otherwise or otherwise impossible as would be known to one of ordinary skill in the art. Accordingly, the disclosure is intended to encompass all such alternatives, modifications and variations which fall within the scope and spirit of the disclosure and the following claims.

1. (canceled)

2. The method of claim 8, wherein said first work function material layer is in contact with said first portion of said gate dielectric layer after formation of said first conductive material portion, and said second work function material layer is in contact with said second portion of said gate dielectric layer after formation of said second conductive material portion.

3. The method of claim 8, wherein one of said first and second conductive material portions are formed directly on said TaAl layer.

4. The method of claim 8, wherein a gate electrode comprising said TaAl and one of said first and second conductive material portions has a first work function that is closer to a conduction band of silicon than a mid-band gap level of silicon, and another gate electrode comprising said metallic nitride layer and another of said first and second conductive material portions has a second work function that is closer to a valence band of silicon than said mid-band gap level of silicon.

5. The method of claim 8, wherein one of said first and second conductive material portions is formed directly on said first work function material layer, and another of said first and second conductive material portions is formed directly on said second work function material layer.

6. The method of claim 8, wherein a portion of said TaAl layer is formed directly on said metallic nitride layer, wherein one of said first and second conductive material portions contacts said portion of said TaAl layer upon formation.

7. The method of claim 8, wherein a portion of said metallic nitride layer is formed directly on said TaAl layer, wherein one of said first and second conductive material portions contacts said portion of said metallic nitride layer upon formation.

8. A method of forming a semiconductor structure, said method comprising:
forming a first gate cavity and a second gate cavity above a semiconductor portion, wherein each of said first gate cavity and said second gate cavity is laterally surrounded by a planarization dielectric layer, wherein a top surface of said semiconductor portion is exposed at a bottom of each of said first and second gate cavities;
forming a gate dielectric layer within said first and second gate cavities;
forming a first work function material layer directly on a first portion of said gate dielectric layer in said first gate cavity and a second work function material layer directly on a second portion of said gate dielectric layer in said second gate cavity, wherein one of said first and second work function material layers is a TaAl layer and another of said first and second work function material layers is a metallic nitride layer, wherein an atomic percentage of tantalum is from 10% to 99%, and an atomic percentage of aluminum is from 1% to 90% in said TaAl layer; and
filling said first gate cavity and said second gate cavity with a conductive material, wherein a first conductive material portion is formed within said first gate cavity and a second conductive material portion is formed within said second gate cavity.

9. A method of forming a semiconductor structure, said method comprising:
forming a first gate cavity and a second gate cavity above a semiconductor portion, wherein each of said first gate cavity and said second gate cavity is laterally surrounded by a planarization dielectric layer, wherein a top surface of said semiconductor portion is exposed at a bottom of each of said first and second gate cavities;
forming a gate dielectric layer within said first and second gate cavities;
forming a first work function material layer directly on a first portion of said gate dielectric layer in said first gate cavity and a second work function material layer directly on a second portion of said gate dielectric layer in said second gate cavity, wherein one of said first and second work function material layers is a TaC layer and another of said first and second work function material layers is a metallic nitride layer, wherein an atomic percentage of tantalum is from 20% to 80%, and an atomic percentage of aluminum is from 20% to 80% in said TaC layer; and alloy of tantalum and carbon
filling said first gate cavity and said second gate cavity with a conductive material, wherein a first conductive material portion is formed within said first gate cavity and a second conductive material portion is formed within said second gate cavity.

10. A method of forming a semiconductor structure, said method comprising:
forming a first gate cavity and a second gate cavity above a semiconductor portion, wherein each of said first gate cavity and said second gate cavity is laterally surrounded by a planarization dielectric layer, wherein a top surface of said semiconductor portion is exposed at a bottom of each of said first and second gate cavities;
forming a gate dielectric layer within said first and second gate cavities;
forming a first work function material layer directly on a first portion of said gate dielectric layer in said first gate cavity and a second work function material layer directly on a second portion of said gate dielectric layer in said second gate cavity, wherein one of said first and second work function material layers is a TaAlC layer and another of said first and second work function material layers is a metallic nitride layer, wherein an atomic percentage of tantalum is from 15% to 80%, an atomic percentage of aluminum is from 1% to 60%, and an atomic percentage of carbon is from 15% to 80% in said TaAlC layer; and
filling said first gate cavity and said second gate cavity with a conductive material, wherein a first conductive material portion is formed within said first gate cavity and a second conductive material portion is formed within said second gate cavity.

11. The method of claim 9, wherein said first work function material layer is in contact with said first portion of said gate dielectric layer after formation of said first conductive material portion, and said second work function material layer is in contact with said second portion of said gate dielectric layer after formation of said second conductive material portion.

12. The method of claim 9, wherein one of said first and second conductive material portions are formed directly on said TaC layer.

13. The method of claim 9, wherein a gate electrode comprising said TaC layer and one of said first and second conductive material portions has a first work function that is closer to a conduction band of silicon than a mid-band gap level of silicon, and another gate electrode comprising said metallic nitride layer and another of said first and second conductive material portions has a second work function that is closer to a valence band of silicon than said mid-band gap level of silicon.

14. The method of claim 9, wherein one of said first and second conductive material portions is formed directly on said first work function material layer, and another of said first and second conductive material portions is formed directly on said second work function material layer.

15. The method of claim 9, wherein a portion of said TaC layer is formed directly on said metallic nitride layer, wherein one of said first and second conductive material portions contacts said portion of said TaC layer upon formation.

16. The method of claim 9, wherein a portion of said metallic nitride layer is formed directly on said TaC layer, wherein one of said first and second conductive material portions contacts said portion of said metallic nitride layer upon formation.

17. The method of claim 10, wherein said first work function material layer is in contact with said first portion of said gate dielectric layer after formation of said first conductive material portion, and said second work function material layer is in contact with said second portion of said gate dielectric layer after formation of said second conductive material portion.

18. The method of claim 10, wherein a gate electrode comprising said TaAlC layer and one of said first and second conductive material portions has a first work function that is closer to a conduction band of silicon than a mid-band gap level of silicon, and another gate electrode comprising said metallic nitride layer and another of said first and second conductive material portions has a second work function that is closer to a valence band of silicon than said mid-band gap level of silicon.

19. The method of claim 10, wherein one of said first and second conductive material portions is formed directly on said first work function material layer, and another of said first and second conductive material portions is formed directly on said second work function material layer.

20. The method of claim 10, wherein a portion of said TaAlC layer is formed directly on said metallic nitride layer, wherein one of said first and second conductive material portions contacts said portion of said TaAlC layer upon formation.

21. The method of claim 10, wherein a portion of said metallic nitride layer is formed directly on said TaAlC layer, wherein one of said first and second conductive material portions contacts said portion of said metallic nitride layer upon formation.
